(19) United States
(12) Patent Application Publication
(10) Pub. No.: US 2026/0057128 A1
(43) Pub. Date: Feb. 26, 2026

(54) METHOD AND SYSTEM OF MASS PRODUCING CUSTOM FIT FURNITURE

(71) Applicant: Paramorph LLC, Seal Beach, CA (US)

(72) Inventor: Colin Michael DECKNER, Seal Beach, CA (US)

(73) Assignee: Paramorph LLC, Seal Beach, CA (US)

(21) Appl. No.: 18/811,306

(22) Filed: Aug. 21, 2024

(51) Int. Cl. G06F 30/17

(52) U.S. Cl. CPC G06F 30/17

(57) ABSTRACT

The Abstract of the Disclosure is provided to allow the reader to quickly identify the nature of the technical disclosure. It is submitted with the understanding that it will not be used to interpret or limit the scope or meaning of the claims. In addition, in the foregoing Detailed Description, it can be seen that various features are grouped together in various examples for the purpose of streamlining the disclosure. This method of disclosure is not to be interpreted as reflecting an intention that any claim requires more features than the claim expressly recites. Rather, as the following claims reflect, inventive subject matter lies in less than all features of a single disclosed example. Thus, the following claims are hereby incorporated into the Detailed Description, with each claim standing on its own as a separately claimed subject matter.

### BACKGROUND

Furniture is at a unique point for evolution thanks to the digital age of design and fabrication. Technology has allowed furniture manufactures to create more versatile designs and to change designs more rapidly, resulting in creative and quickly evolving designs that respond to customers'latest needs and newest trends. Furthermore, modern shipping platforms allow manufacturers to build and ship furniture from many places in the world. While use of modern technology, manufacturing and shipping mechanisms has led to creative and low-cost furniture, current methods of designing and manufacturing furniture lead to furniture that is uncomfortable or undesirable for many people. Furthermore, while a local carpenter may be able to design and custom-build a piece of furniture based on an individual's specific needs, such furniture would be very expensive to design and build, thus making custom designed and custom-made furniture inaccessible to most people.

Hence, there is a need for improved methods and systems of mass producing custom fit furniture.

### SUMMARY

In one general aspect, the instant disclosure presents a data processing system for production of custom-fit furniture, the data processing system having a processor and a memory in communication with the processor wherein the memory stores executable instructions that, when executed by the processor alone or in combination with other elements, cause the data processing system to perform multiple functions. The functions include receiving measurement data that quantify a plurality of proportions of a human body; determining, via a custom-fit design engine, based on the measurement data, dimensions for one or more parts that make up a furniture item; and generating an electronic design file based on the determined dimensions, the electronic design file providing a specification of dimensions and one or more shapes for the one or more parts of the furniture item, the electronic design file identifying a plurality of lines along a material from which the one or more parts of the furniture item are to be produced, and the electronic design file identifying a bend to be made along one or more of the plurality of lines and an indication of a number of degrees of each bend along the plurality of lines to form the one or more parts of the furniture item. The electronic design file is used to cut a sheet of a bendable material by a computer-aided manufacturing machine in accordance with the specification of the dimensions.

In yet another general aspect, the instant disclosure presents a method for mass production of custom-fit furniture. In some implementations, the method includes receiving measurement data that quantify a plurality of proportions of a human body via a user interface of an application; receiving one or more parameters related to a desired furniture item; determining, via a custom-fit design engine, based on at least the measurement data and the one or more parameters, dimensions for one or more parts that make up the desired furniture item; and generating an electronic design file based on the determined dimensions, the electronic design file providing a specification of dimensions and one or more shapes for the one or more parts of the furniture item, the electronic design file identifying a plurality of lines along a material from which the one or more parts of the furniture item are to be produced, and the electronic design file identifying a bend to be made along one or more of the plurality of lines and an indication of a number of degrees of each bend along the plurality of lines to form the one or more parts of the furniture item. The electronic design file is used to cut a sheet of a bendable material by a computer-aided manufacturing machine in accordance with the electronic design file.

In a further general aspect, the instant application describes custom-fit furniture item which includes a plurality of parts, each part having one or more dimensions and each part forming a shape; and one or more connecting elements for connecting the plurality of parts to produce the custom-fit furniture item. The one or more dimensions are determined based on measurement data that quantify a plurality of proportions of a human body, and the plurality of parts are made from a material which is cut using an electronic design file generated for the custom-fit furniture item. The electronic design file identifies a plurality of lines along the material and identifying a bend to be made along one or more of the plurality of lines and an indication of a number of degrees of each bend along the plurality of lines to form the plurality of parts of the furniture item.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

The drawing figures depict one or more implementations in accord with the present teachings, by way of example only, not by way of limitation. In the figures, like reference numerals refer to the same or similar elements. Furthermore, it should be understood that the drawings are not necessarily to scale.

FIG. 1 depicts an example system upon which aspects of this disclosure may be implemented.

FIG. 2 depicts an example of elements involved in generating a design file for a custom-fit furniture.

FIG. 3 depicts examples of parameters measured for generating a custom-fit furniture.

FIGS. 4A-E illustrates examples of chairs generated using a system for mass production of custom-fit furniture.

FIG. 5 depicts an example of unassembled pieces of a custom-fit chair.

FIG. 6 is a flow diagram depicting an exemplary method for generating a design file for use in mass producing custom-fit furniture.

FIG. 7 is a block diagram illustrating an example software architecture, various portions of which may be used in conjunction with various hardware architectures herein described.

FIG. 8 is a block diagram illustrating components of an example machine configured to read instructions from a machine-readable medium and perform any of the features described herein.

### DETAILED DESCRIPTION

Modern technology has enabled furniture manufacturers to streamline their manufacturing processes and utilize design elements that assist the manufacturers achieve efficiency and increased customer satisfaction by quickly adapting to changing design trends. Furthermore, modern transportation mechanisms have enabled manufacturers to build furniture in locations that are geographically distant (often substantially distant) from buyers. While these advancements have been helpful to manufacturers, they often result in mass produced furniture that does not fit the needs of many users. Mass producing furniture often requires furniture manufacturers to design their furniture based on an average person's body proportions. The design is then used to mass produce identical products in large quantities. As a result, furniture is often designed with dimensions that provide comfort for a person of average body proportions. However, most people do not have average body proportions. Furthermore, many designers give more weight to aesthetical elements of furniture than comfort. This results in the resulting furniture being uncomfortable/unfit for many users. Moreover, while custom designing furniture based on a given person's body measurements may be achieved by a carpenter, the process requires extensive personalized design and/or handmaking the furniture. This often results in expensive furniture which is inaccessible to most people. Thus, there exists a technical problem of lack of adequate mechanisms for efficiently mass-producing custom-fit furniture.

To address these technical problems and more, in an example, this description provides technical solutions for a system that receives a person's measured body proportions, preferences or other custom parameters and uses the received parameters to generate a design for a given piece of furniture with dimensions that correspond with the custom parameters. The system generates a custom design file for the furniture, where the design file can be used by a manufacturer to produce unassembled pieces which can then be used to assemble the furniture in an efficient manner. In an implementation, the design file is used to cut a single sheet of a bendable material (e.g., steel) which is capable of being assembled into a piece of furniture such as a chair in an efficient manner (e.g., using simple tools and minimal time such as 1 hour). The sheet of bendable material is cut via a computer-aided manufacturing machine in an efficient manner. Thus, the system creates files for digital fabrication in a custom-tailored mass-produced hybrid style of manufacturing. As a result, the manufacturer can produce pieces of a custom furniture in a cost-effective manner. This allows the manufacturer to mass produce custom furniture cost-effectively, thus making custom-fit comfortable furniture more affordable and more accessible to everyday users. In some implementations, the user can use an application to generate the design file and then use the design file to locally produce the custom-fit furniture (e.g., by using a local computer-aided manufacturing machine such as a laser cutting facility). The user can, for example, use a custom design file to cut a single sheet of bendable material, which can then be bent and assembled locally and efficiently into a finished custom-fit furniture. This is because the use of a single sheet of bendable material enables a non-skilled user (e.g., someone who is not a carpenter and has minimal furniture making skills) to assemble the custom-fit furniture. This results in decentralized manufacturing, which reduces shipping costs, is environmentally efficient and does not require warehouses or local furniture stores.

As will be understood by persons of skill in the art upon reading this disclosure, benefits and advantages provided by such implementations can include, but are not limited to, a technical solution to the technical problems of lack of mechanisms for efficiently mass-producing custom-fit furniture. The technical solutions enable use of an algorithm to generate a design file based on a user's measurements and other desired parameters. The design is simple enough that it can be generated locally or be produced in a cost-effective manner by a manufacturer. This improves the current state of mechanical production and furniture manufacturing and results in increased customer satisfaction and increased access to comfortable furniture, in particular, for people with atypical bodies.

The terms “furniture”, “furniture item” or “furniture object” as used herein refers to an object intended to support various human activities such as seating, sleeping, eating, working, or storage. Examples of furniture as used herein include a chair, table, sofa, desk, loveseat, bed and the like.

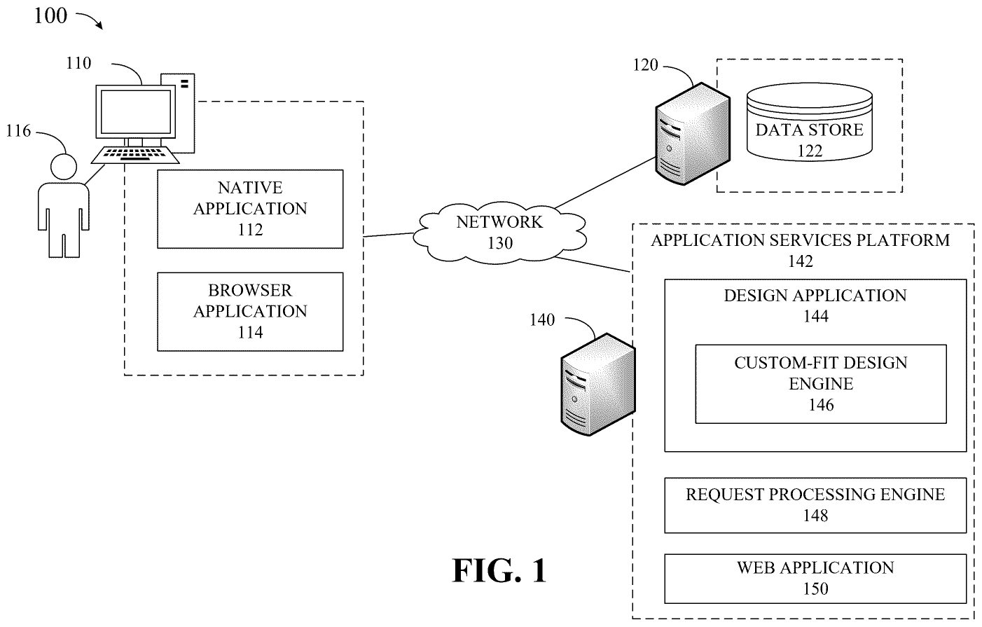

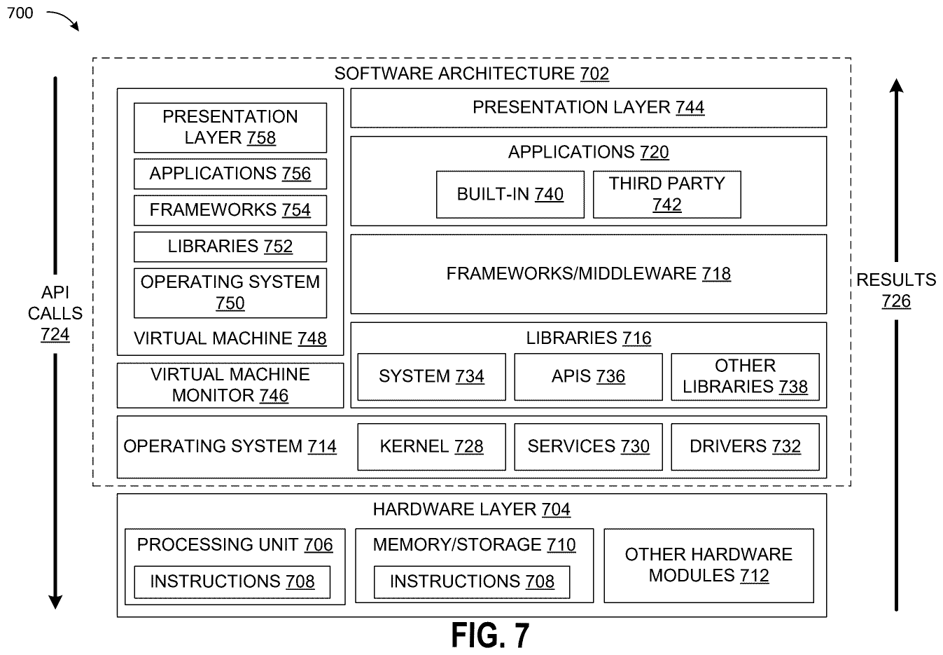

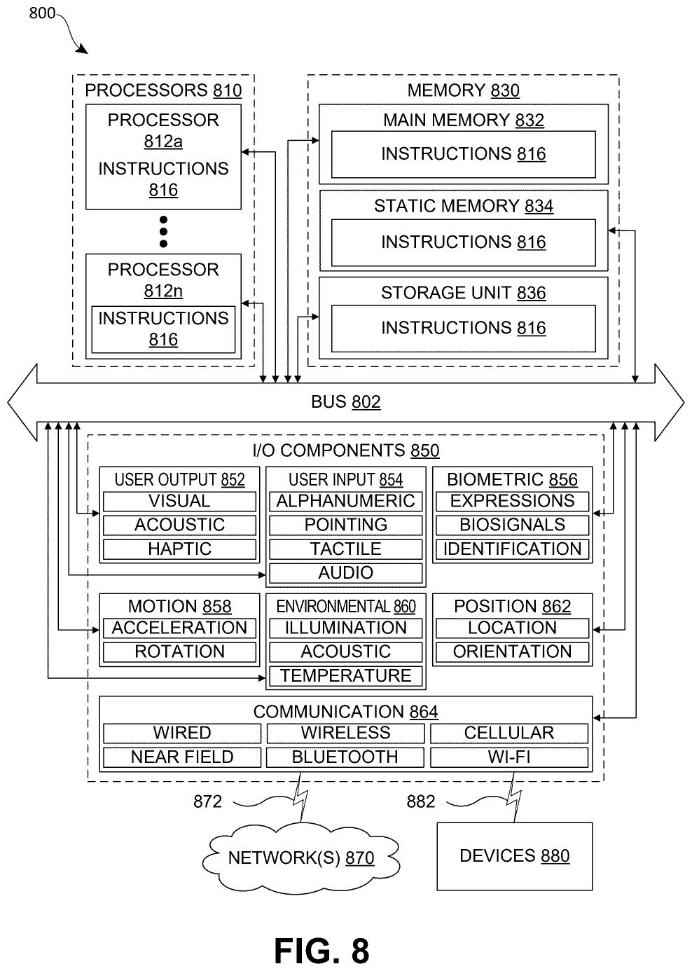

FIG. 1 illustrates an example system 100, upon which aspects of this disclosure are implemented. The system 100 includes a client device 110, a data storage server 120 and a server 140 hosting an application services platform 142. While shown as one server, the servers 120 and 140 may represent a plurality of servers that provide data storage and/or various other services. The client device 110 may be a type of personal, business or handheld computing device having or being connected to input/output elements that enable a user to interact with various applications (e.g., native application 112 or browser application 114). The client device 110 may be utilized by a user 116 to utilize a design application or another application or page such as the application 112 or 114 to provide input parameters such as measurements and other custom parameters for a desired custom furniture. The client device 110 may also be utilized by a manufacturer or builder to view and/or use a generated design file in order to produce one or part for and/or build a piece of furniture. Examples of suitable client devices 110 include but are not limited to personal computers, desktop computers, laptop computers, mobile telephones, smart phones, tablets, phablets, smart watches, wearable computers, gaming devices/computers, televisions; and the like. While one client device is displayed in FIG. 1, any number of client devices may be used in the system 100. The internal hardware structure of a client device is discussed in greater detail with respect to FIGS. 7 and 8.

The client device 110 includes a native application 112 and a browser application 114. The applications 112 and 114 are representative of one or more software programs executed on the client device 110 that configure the device to be responsive to user input to allow the user to provide custom parameters for a desired piece of furniture or to utilize a design file to make one or more parts for a build a custom-fit furniture. Examples of suitable applications include but are not limited to a design application and a web application. The native application 114 is a web-enabled native application, in some implementations, that provides an interface for entering user input and/or viewing or utilizing a design file. The browser application 114 can be used for accessing and viewing web-based content provided by the application services platform 142. In such implementations, the application services platform 142 implements one or more web applications, such as the web application 150, that enables users to communicate with the application services platform to create and/or use a design file. The application services platform 110 supports both the native application 112 and the web application 150, and the users may choose which approach best suits their needs.

The client device 110 is connected to the server 120 via a network 130. The network 130 may be a wired or wireless network(s) or a combination of wired and wireless networks that connect one or more elements of the system 100. In some implementations, the network 130 includes one or more local area networks (LAN), wide area networks (WAN) (e.g., the Internet), public networks, private networks, virtual networks, mesh networks, peer-to-peer networks, and/or other interconnected data paths across which multiple devices may communicate. In some examples, the network 130 is coupled to or includes portions of a telecommunications network for sending data in a variety of different communication protocols. In some implementations, the network 130 includes Bluetooth® communication networks or a cellular communications network for sending and receiving data including via short messaging service (SMS), multimedia messaging service (MMS), hypertext transfer protocol (HTTP), direct data connection, WAP, email, and the like.

The server 120 is connected to or includes the data store 122 which functions as a repository in which databases relating to design files and the like may be stored. As such, the data store 122 may function as a cloud storage site for storing files related to designing custom-fit design files. Although shown as a single data store, the data store 122 may be representative of multiple storage devices and data stores which are accessible by the client device 110 and/or application services platform 142. In some implementations, the data store 122 is included in or a part of the application services platform 142.

The application services platform 142 includes a request processing unit 148, design application 144 and the web application 150. The request processing unit 148 is configured to receive requests from an application implemented by the native application 112 of the client device 110 and/or the web application 150 of the application services platform 142 and transmit the request to an appropriate element of the application services platform 142 such as the design management application 144. In some implementations, the request is directly submitted to the design application 144 or custom-fit design engine 146. In the example implementation shown in FIG. 1, the application services platform 142 is implemented as a cloud-based service or set of services. However, in other implementations, the application services platform 142 can be implemented on a server of a local network.

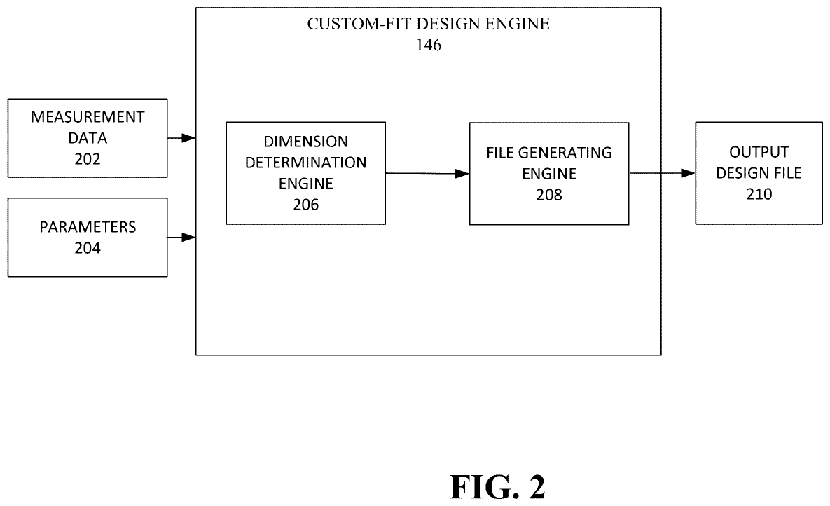

The design application 144 includes a custom-fit design engine 146. In some implementations, the custom-fit design engine is a software program (i.e., an application) designed for receiving custom-fit parameters and generating a design file for a desired piece of furniture based on the received parameters. In one implementation, the custom-fit design engine is an algorithm created in a visual programming language (e.g., Grasshopper), which is an environment that runs within the design application 144. In some examples, the design application 144 is a 3D computer-aided design (CAD) application such as Rhinoceros 3D. In an example, the custom-fit design engine 146 is created by dragging components unto a design canvas, where the output of the components are connected to inputs of subsequent components to create the application. In this manner, the custom-fit design engine 146 is created to generate a design file (e.g., a 3D design) based on input parameters supplied to the custom-fit design engine 146. While the custom-fit design engine 146 is displayed as being part of the application services platform 142, in other implementations, the custom-fit design engine 146 is implemented independently of the application services platform 142. In some implementations, the custom-fit design engine 146 is executed directly on a server or on a client device. Other implementations of the system 100 may include additional elements and/or a different combination of elements. The structure and various elements of the custom-fit design engine 146 are discussed in greater detail with respect to FIG. 2.

FIG. 2 depicts an example of elements involved in generating a design file for a custom-fit furniture. In some implementations, a user enters measurement data 202 into a user interface (UI) screen of an application or service to specify the measurement they desire to use for a custom-fit furniture. The application then subsequently transmits the measurement data 202 to the custom-fit design engine 146 for use. In other implementations, the measurement data 202 is transmitted to another user, such as an employee of a furniture manufacturing facility, which will subsequently provide the measurements to the custom-fit design engine 146. The measurement data may include measurements of various body proportions. In an example, the user may provide one or more of the measurement data and the custom-fit design engine 146 may estimate the remaining measurements based on the entered data. In another example, the user may provide one or more of the measurement data and the custom-fit design engine 146 may use predetermined measurement data (e.g., based on a database of body measurements, etc.) for the missing measurements. The number and type of measurements needed may vary depending on the type of furniture.

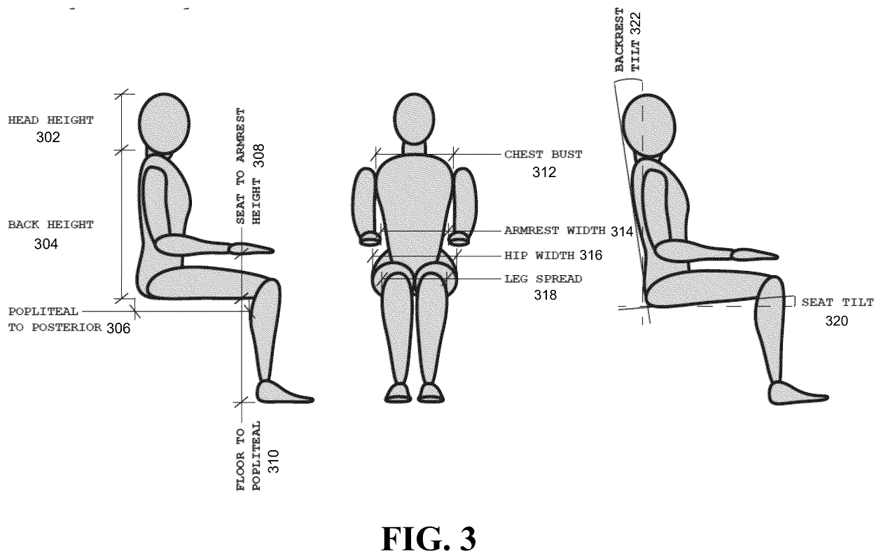

FIG. 3 depicts examples of parameters measured for generating a custom-fit furniture. The example parameters depicted in FIG. 3 may be used for designing a piece of furniture used for sitting such as a chair, sofa or loveseat. Moreover, some or all of these parameters may be used to design furniture such as desks, tables, beds and the like. The measurements include a head height 302 which measure the height of a person's head, a back height 304 which measures the distance between the person's neck and their lower back, and a popliteal to posterior measurement 306, which measures the distance between person's hip and back of the knee while sitting. Additional measurements include a seat to armrest height 308 which measures the distance between the back of the thigh to a location at which the user is comfortable resting their arm. The floor to popliteal measurement 310 measures the distance between the back of the thigh to the floor. Further measured parameters that can be used to customize a piece of furniture include chest bust 302, armrest width 314, hip width 316 and leg spread distance 318. The chest bust measurement 312 measures the distance between the shoulders, while the armrest width 314 measures the distance between the two arms in a sitting position. The hip width 613 measures the distance between the hips and the leg spread 318 measures the distance between the knees when sitting in a comfortable position. To further customize the furniture, additional measurements include backrest tilt 322, which measures the distance between the person's head when sitting upright in a vertical position and when tilting back in a comfortable position, and seat tilt 320 which measures the tilt of the hips when the person is sitting in a titled comfortable position. While FIG. 3 depicts 11 measured parameters, other parameters may be used for different types of furniture or different types of designs.

Referring back to FIG. 2, once the measured data 202, which may include all or some of the measured parameters displayed in FIG. 3 are provided to the custom-fit design engine 146, the provided measurement data 202 is used to determine dimensions for the desired furniture. In some implementations, in addition to the measurement data 202, other parameters 204 are also provided. The parameters 204 may include a selection of a type of furniture (e.g., a type of chair or selection from among a set of available furniture piece options), male/female selection for the user, which may help better customize the furniture for the correct body type, material selection (e.g., wood or steel), color selection and the like.

Some or all of the parameters 204 (e.g., male/female selection, furniture type selection, material selection, etc.) and the measurement data 202 is provided to the dimension determination engine 206 to be used in determining the proper dimensions for each part of the furniture. In an example, a chair includes multiple parts such as armrest, seat portion, back portion and legs, and the dimension determination engine 206 determines the dimensions of each of the required parts such as the height of the legs, the width and length of the seat and the like. The dimension determination engine 206 may use a predetermined dataset that identifies dimensions that correspond with certain measurement data ranges. In an example, the predetermined dataset is generated using research and examination of dimensions that provide comfort for users within each measurement data range as well as user submitted dimensions. In another example, the dimension determination engine 206 uses a classifier or artificial intelligence to determine the proper dimensions.

Once the dimensions for the desired/selected product have been determined, the dimensions are provided to the file generating engine 208. In an example, the file generating engine 208 is an application or algorithm that generates a design file such as the output design file 201, based on parameters 204 such as the type of furniture selected and the material selection as well as the determined dimensions for the selected furniture. The output design file 210 is generated such that it can be used by any user having access to a design application that can execute the design file to produce the desired furniture based on the customized dimensions. In an example, the output design file 210 is a CAD file that can be viewed using a CAD application. The output design file 210 can be provided by the custom-fit design engine 146 for storage, transmission and/or future use. In an example, the output design file 210 is provided to the design application 144 which can provide it for display to the furniture manufacturer or the requesting user, as needed, for future use. In an example, the output design file 210 is transmitted to the requesting user so that the user can use the design file, as needed for building their own custom-fit furniture locally and/or at home. In some implementations, the output design file 210 can be used by a computer-aided manufacturing machine to generate one or more pieces for the furniture. The computer-aided manufacturing machine may include a laser computer-aided manufacturing machine, a plasma computer-aided manufacturing machine, a waterjet computer-aided manufacturing machine or a router computer-aided manufacturing machine. In this manner, the custom-fit design engine 146 quickly and efficiently generates a design file for a custom-fit furniture based on a person's actual body proportions. In some implementations, the design file is generated in a manner that enables the furniture to be cut from a single sheet of material, thus ensuring ease of assembly and production. This enables mass production of custom-fit furniture and leads to custom-fit furniture being accessible and available to many users.

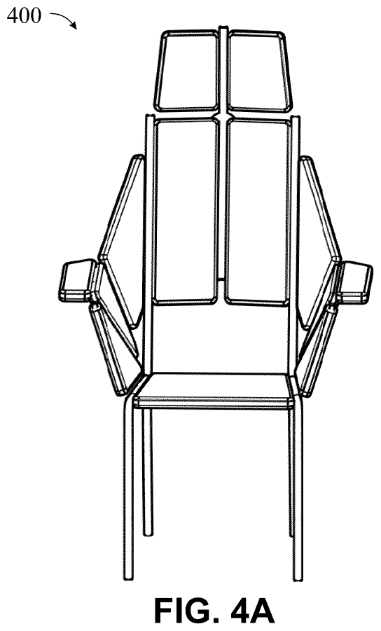

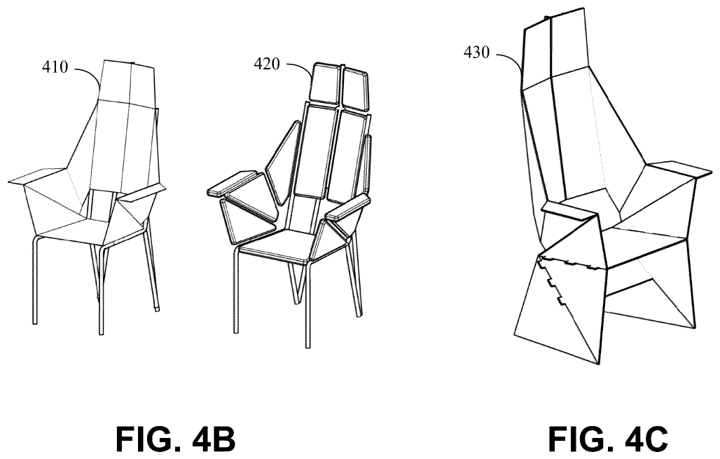

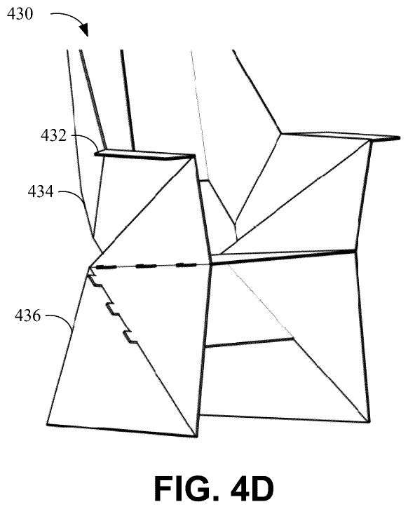

FIGS. 4A-D illustrates examples of chairs generated using a system for mass production of custom-fit furniture. FIG. 4A depicts an example prototype for a customizable chair 400 made from wood, steel and copper. The chair 400 includes multiple wood pieces that form the back, bottom and side portions, hand forged steel legs and a steel spine. In some implementations, the spine or the legs have a copper-colored finish. The design file for the chair 400 would include dimensions for each of the wood pieces, as well as dimensions for the legs and the spine. The design file would also identify the materials for each portion.

FIG. 4B depicts examples of two prototypes for a customizable chair, one a chair 310 made from steel and another, a chair 420, made from wood and steel. The chair 410 is a prototype for a customizable chair that is made from steel and/or copper. Chair 410 may be easier to mass produce since a computer-aided manufacturing machine such as a laser computer-aided manufacturing system, a plasma computer-aided manufacturing machine, a waterjet computer-aided manufacturing machine or a router computer-aided manufacturing machine can be used to cut the pieces of the bendable material. Chair 420 is similar in design to the chair 400 of FIG. 4A and uses multiple materials such as wood, steel and copper. Both chairs 410 and 420 are customizable and can be produced using a design file that is customized based on individual body proportions.

FIG. 4C depicts a prototype for a customizable chair 430 that is made entirely of steel. This prototype uses steel for various portions of the chair as well as for connecting elements that connect two or more portions to each other. Each of the chair portions such as the back, seat portion, legs, armrests and the like have dimensions that are adjustable and can be changed based on user preferences and measurements. FIG. 4D depicts a magnified side view of the customizable chair 430, which displays an armrest 432, top side portion 434 and bottom side portion 436. As illustrated, each of the armrest 432, top side portion 434 and bottom side portion 436 are made from the same material. This ensures ease of manufacturing, reduces costs and increases accessibility. FIG. 4E depicts a side view of the customizable chair 430 which displays the back of the chair 430 and the connecting element 438 connecting the two portions of the back portion.

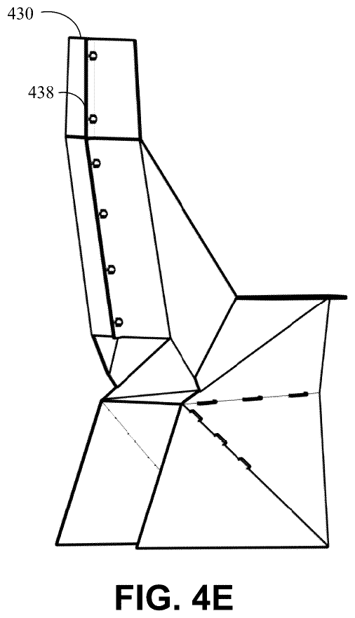

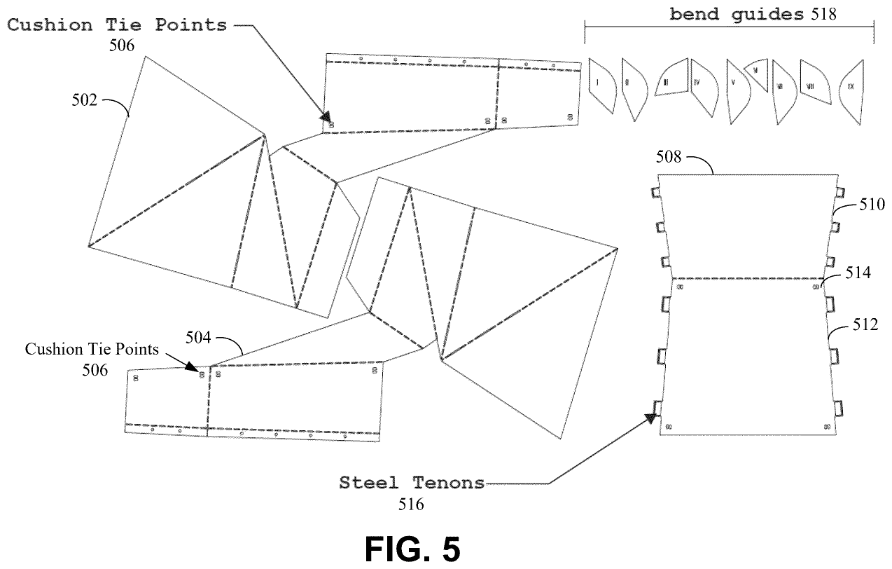

FIG. 5 depicts an example design for unassembled pieces of a custom-fit chair generated using a system for mass producing custom-fit furniture. The design includes designs for two side portions 502 and 504, which are used to manufacture the side portions of the custom-fit chair. Each of the side portion 502 and 504 may include cushion tie points 506 for enabling the user to attach a cushion to the chair. The cushion tie points 506 may comprise of openings that are configured to enable a person to pass through a cushion tie. In the illustrated example, the design includes 4 cushion tie points 506 on each side portion.

The design also includes a design for the main chair portion 508 which includes the seat portion 512 and the back portion 510. The seat portion includes a plurality of cushion tie points 506 which correspond in shape and size the cushion tie points 506 of the side portions. The main portion 508 also includes a plurality of steel tenons 516 that act as connecting elements and are used when assembling the chair in order to attach the side portions to the main portion 510. Thus, the steel tenons 516 attach the seat portion 512 to the side portions. In an example, this is achieved by the steel tenons 516 sliding in the side portions through grooves (e.g., opening) in the side portion. The steel tenons 516 can then be bent to lock the chair together.

The design also includes bend guides 518. The guides 518 are used to enable hand bending the pieces as needed during assembly. As discussed before, the angle of each of the portions is generated, as needed to ensure that the chair is custom fit for a given user. This design can be used to cut the custom-fit chair from a single sheet of bendable material such as steel. This can be done locally or individually to produce custom-fit chairs at a large scale for users anywhere there is access to computer-aided manufacturing machine such as a laser cutting. The various portions can then be used to quickly, efficiently, and inexpensively assemble the custom-fit chair. In an example, after cutting the pieces, the bend guides 518 are used as angle finder guides to hand bend the pieces into the desired forms. This results in a chair that uses the one design file to custom-fit a chair to any desired size. This provides an improved manufacturing process that results in decentralized manufacturing, requires no warehouses and enables short shipping distances. Any geographical location with a computer-aided manufacturing machine could become a manufacturing hub for the custom-fit chair. The design can be used to either locally produce and assemble or produce the pieces and ship unassembled.

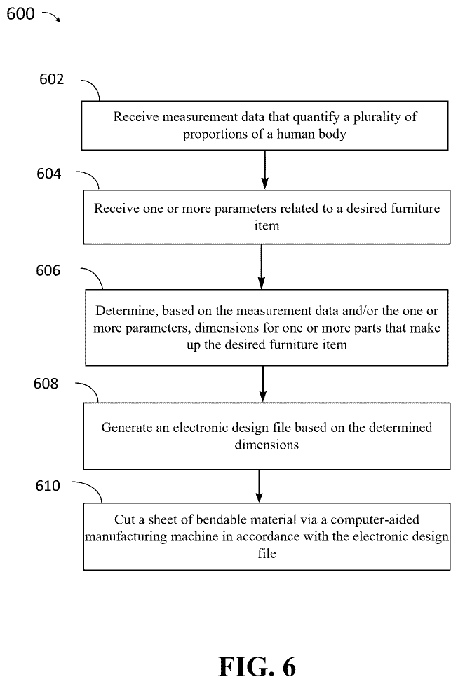

FIG. 6 is a flow diagram depicting another exemplary method for generating a design file that can be used to produce a custom-fit furniture. At least some of the steps of method 600 are performed by a custom-fit design engine such as the custom-fit design engine 146 of FIGS. 1 and 2 and/or an application such as applications 112/114 of FIG. 1. Method 600 begins and proceeds to receive measurement data that quantify a plurality of proportions of a human body, at 602. The measurement data may be received via a user interface of an application, such as a web application or a design application and may be submitted by a user ordering a custom-fit furniture or maybe provided by an agent (e.g., employee, administrator, owner) of a furniture manufacturing entity that has received the measurement data for a given customer (e.g., via email, instant message, in-person visit, telephone call, etc.) and provides the data as an input to the system. After receiving the measurement data, method 600 proceeds to receive one or more parameters related to a desired furniture item, at 604. The parameters may include a selection of a specific furniture item (e.g., custom-fit chair), a selection of the user's sex, a selection of color or material for the desired furniture item and the like.

After receiving the measurement data and the one or more parameters, method 600 proceeds to determine, via a custom-fit design engine, based on the measurement data and/or the parameters, dimensions for one or more parts that make up the desired furniture item, at 606. The dimensions may be determined based on the various parameters, the desired furniture item and the measurement data such that the resulting custom-fit furniture item is designed to provide maximized comfort to the intended user.

Once the dimensions are determined, an electronic design file is generated based on the determined dimensions, at 608. The electronic design file provides a specification of dimensions and one or more shapes for the one or more parts of the furniture item. The electronic design file also identifies a plurality of lines along a material from which the one or more parts of the furniture item are to be produced. Moreover, the electronic design file identifies a bend to be made along one or more of the plurality of lines and an indication of a number of degrees of each bend along the plurality of lines to form the one or more parts of the furniture item.

After the electronic design file is generated, the file is used to cut a sheet of a bendable material by a computer-aided manufacturing machine in accordance with the electronic design, at 610. The computer-aided manufacturing machine may include a laser computer-aided manufacturing machine, a plasma computer-aided manufacturing machine, a waterjet computer-aided manufacturing machine or a router computer-aided manufacturing machine. The furniture may be one of a chair, a table, a bench, a desk, a sofa, a bed or a loveseat. The cut sheet of bendable material is then used to bend one or more parts of the furniture item along the bend made along the one or more of the plurality of lines. The bending may be done by a machine or by a human. The one or more parts are then used to assemble the custom-fit furniture item.

FIG. 7 is a block diagram 700 illustrating an example software architecture 702. This architecture may be used in each of the various services described above. Also, various portions of this architecture may be used in conjunction with various hardware architectures herein described, which may implement any of the above-described features. FIG. 7 is a non-limiting example of a software architecture, and it will be appreciated that many other architectures may be implemented to facilitate the functionality described herein. The software architecture 702 may execute on hardware such as a machine 800 of FIG. 8 that includes, among other things, processors 810, memory 830, and Input/Output (I/O) components 850. A representative hardware layer 704 is illustrated and can represent, for example, the machine 800 of FIG. 8. The representative hardware layer 704 includes a processing unit 706 and associated executable instructions 708. The executable instructions 708 represent executable instructions of the software architecture 702, including implementation of the methods, modules and so forth described herein. The hardware layer 704 also includes a memory/storage 710, which also includes the executable instructions 708 and accompanying data. The hardware layer 704 may also include other hardware modules 712. Instructions 708 held by processing unit 706 may be portions of instructions 708 held by the memory/storage 710.

The example software architecture 702 may be conceptualized as layers, each providing various functionality. For example, the software architecture 702 may include layers and components such as an operating system (OS) 714, libraries 716, frameworks 718, applications 720, and a presentation layer 744. Operationally, the applications 720 and/or other components within the layers may invoke API calls 724 to other layers and receive corresponding results 726. The layers illustrated are representative in nature and other software architectures may include additional or different layers. For example, some mobile or special purpose operating systems may not provide the frameworks/middleware 718.

The OS 714 may manage hardware resources and provide common services. The OS 714 may include, for example, a kernel 728, services 730, and drivers 732. The kernel 728 may act as an abstraction layer between the hardware layer 704 and other software layers. For example, the kernel 728 may be responsible for memory management, processor management (for example, scheduling), component management, networking, security settings, and so on. The services 730 may provide other common services for the other software layers. The drivers 732 may be responsible for controlling or interfacing with the underlying hardware layer 704. For instance, the drivers 732 may include display drivers, camera drivers, memory/storage drivers, peripheral device drivers (for example, via Universal Serial Bus (USB)), network and/or wireless communication drivers, audio drivers, and so forth depending on the hardware and/or software configuration.

The libraries 716 may provide a common infrastructure that may be used by the applications 720 and/or other components and/or layers. The libraries 716 typically provide functionality for use by other software modules to perform tasks, rather than rather than interacting directly with the OS 714. The libraries 716 may include system libraries 734 (for example, C standard library) that may provide functions such as memory allocation, string manipulation, file operations. In addition, the libraries 716 may include API libraries 736 such as media libraries (for example, supporting presentation and manipulation of image, sound, and/or video data formats), graphics libraries (for example, an OpenGL library for rendering 2D and 3D graphics on a display), database libraries (for example, SQLite or other relational database functions), and web libraries (for example, WebKit that may provide web browsing functionality). The libraries 716 may also include a wide variety of other libraries 738 to provide many functions for applications 720 and other software modules.

The frameworks 718 (also sometimes referred to as middleware) provide a higher-level common infrastructure that may be used by the applications 720 and/or other software modules. For example, the frameworks 718 may provide various graphic user interface (GUI) functions, high-level resource management, or high-level location services. The frameworks 718 may provide a broad spectrum of other APIs for applications 720 and/or other software modules.

The applications 720 include built-in applications 740 and/or third-party applications 742. Examples of built-in applications 740 may include, but are not limited to, a contacts application, a browser application, a location application, a media application, a messaging application, and/or a game application. Third-party applications 742 may include any applications developed by an entity other than the vendor of the particular platform. The applications 720 may use functions available via OS 714, libraries 716, frameworks 718, and presentation layer 744 to create user interfaces to interact with users.

Some software architectures use virtual machines, as illustrated by a virtual machine 748. The virtual machine 748 provides an execution environment where applications/modules can execute as if they were executing on a hardware machine (such as the machine 800 of FIG. 8, for example). The virtual machine 748 may be hosted by a host OS (for example, OS 714) or hypervisor, and may have a virtual machine monitor 746 which manages operation of the virtual machine 748 and interoperation with the host operating system. A software architecture, which may be different from software architecture 702 outside of the virtual machine, executes within the virtual machine 748 such as an OS 750, libraries 752, frameworks 754, applications 756, and/or a presentation layer 758.

FIG. 8 is a block diagram illustrating components of an example machine 800 configured to read instructions from a machine-readable medium (for example, a machine-readable storage medium) and perform any of the features described herein. The example machine 800 is in a form of a computer system, within which instructions 816 (for example, in the form of software components) for causing the machine 800 to perform any of the features described herein may be executed. The machine 800 may be used to implement any of the services described in the system above.

As such, the instructions 816 may be used to implement modules or components described herein. The instructions 816 cause unprogrammed and/or unconfigured machine 800 to operate as a particular machine configured to carry out the described features. The machine 800 may be configured to operate as a standalone device or may be coupled (for example, networked) to other machines. In a networked deployment, the machine 800 may operate in the capacity of a server machine or a client machine in a server-client network environment, or as a node in a peer-to-peer or distributed network environment. Machine 800 may be embodied as, for example, a server computer, a client computer, a personal computer (PC), a tablet computer, a laptop computer, a netbook, a set-top box (STB), a gaming and/or entertainment system, a smart phone, a mobile device, a wearable device (for example, a smart watch), and an Internet of Things (IOT) device. Further, although only a single machine 800 is illustrated, the term “machine” includes a collection of machines that individually or jointly execute the instructions 816.

The machine 800 may include processors 810, memory 830, and I/O components 850, which may be communicatively coupled via, for example, a bus 802. The bus 802 may include multiple buses coupling various elements of machine 800 via various bus technologies and protocols. In an example, the processors 810 (including, for example, a central processing unit (CPU), a graphics processing unit (GPU), a digital signal processor (DSP), an ASIC, or a suitable combination thereof) may include one or more processors 812a to 812n that may execute the instructions 816 and process data. In some examples, one or more processors 810 may execute instructions provided or identified by one or more other processors 810. The term “processor” includes a multi-core processor including cores that may execute instructions contemporaneously. Although FIG. 8 shows multiple processors, the machine 800 may include a single processor with a single core, a single processor with multiple cores (for example, a multi-core processor), multiple processors each with a single core, multiple processors each with multiple cores, or any combination thereof. In some examples, the machine 800 may include multiple processors distributed among multiple machines.

The memory/storage 830 may include a main memory 832, a static memory 834, or other memory, and a storage unit 836, both accessible to the processors 810 such as via the bus 802. The storage unit 836 and memory 832, 834 store instructions 816 embodying any one or more of the functions described herein. The memory/storage 830 may also store temporary, intermediate, and/or long-term data for processors 810. The instructions 816 may also reside, completely or partially, within the memory 832, 834, within the storage unit 836, within at least one of the processors 810 (for example, within a command buffer or cache memory), within memory at least one of I/O components 850, or any suitable combination thereof, during execution thereof. Accordingly, the memory 832, 834, the storage unit 836, memory in processors 810, and memory in I/O components 850 are examples of machine-readable media.

As used herein, “machine-readable medium” refers to a device able to temporarily or permanently store instructions and data that cause machine 800 to operate in a specific fashion, and may include, but is not limited to, random-access memory (RAM), read-only memory (ROM), buffer memory, flash memory, optical storage media, magnetic storage media and devices, cache memory, network-accessible or cloud storage, other types of storage and/or any suitable combination thereof. The term “machine-readable medium” applies to a single medium, or combination of multiple media, used to store instructions (for example, instructions 816) for execution by a machine 800 such that the instructions, when executed by one or more processors 810 of the machine 800, cause the machine 800 to perform and one or more of the features described herein. Accordingly, a “machine-readable medium” may refer to a single storage device, as well as “cloud-based” storage systems or storage networks that include multiple storage apparatus or devices. The term “machine-readable medium”excludes signals per se.

The I/O components 850 may include a wide variety of hardware components adapted to receive input, provide output, produce output, transmit information, exchange information, capture measurements, and so on. The specific I/O components 850 included in a particular machine will depend on the type and/or function of the machine. For example, mobile devices such as mobile phones may include a touch input device, whereas a headless server or IoT device may not include such a touch input device. The particular examples of I/O components illustrated in FIG. 8 are in no way limiting, and other types of components may be included in machine 800. The grouping of I/O components 850 are merely for simplifying this discussion, and the grouping is in no way limiting. In various examples, the I/O components 850 may include user output components 852 and user input components 854. User output components 852 may include, for example, display components for displaying information (for example, a liquid crystal display (LCD) or a projector), acoustic components (for example, speakers), haptic components (for example, a vibratory motor or force-feedback device), and/or other signal generators. User input components 854 may include, for example, alphanumeric input components (for example, a keyboard or a touch screen), pointing components (for example, a mouse device, a touchpad, or another pointing instrument), and/or tactile input components (for example, a physical button or a touch screen that provides location and/or force of touches or touch gestures) configured for receiving various user inputs, such as user commands and/or selections.

In some examples, the I/O components 850 may include biometric components 856, motion components 858, environmental components 860, and/or position components 862, among a wide array of other physical sensor components. The biometric components 856 may include, for example, components to detect body expressions (for example, facial expressions, vocal expressions, hand or body gestures, or eye tracking), measure biosignals (for example, heart rate or brain waves), and identify a person (for example, via voice-, retina-, fingerprint-, and/or facial-based identification). The motion components 858 may include, for example, acceleration sensors (for example, an accelerometer) and rotation sensors (for example, a gyroscope). The environmental components 860 may include, for example, illumination sensors, temperature sensors, humidity sensors, pressure sensors (for example, a barometer), acoustic sensors (for example, a microphone used to detect ambient noise), proximity sensors (for example, infrared sensing of nearby objects), and/or other components that may provide indications, measurements, or signals corresponding to a surrounding physical environment. The position components 862 may include, for example, location sensors (for example, a Global Position System (GPS) receiver), altitude sensors (for example, an air pressure sensor from which altitude may be derived), and/or orientation sensors (for example, magnetometers).

The I/O components 850 may include communication components 864, implementing a wide variety of technologies operable to couple the machine 800 to network(s) 870 and/or device(s) 880 via respective communicative couplings 872 and 882. The communication components 864 may include one or more network interface components or other suitable devices to interface with the network(s) 870. The communication components 864 may include, for example, components adapted to provide wired communication, wireless communication, cellular communication, Near Field Communication (NFC), Bluetooth communication, Wi-Fi, and/or communication via other modalities. The device(s) 880 may include other machines or various peripheral devices (for example, coupled via USB).

In some examples, the communication components 864 may detect identifiers or include components adapted to detect identifiers. For example, the communication components 864 may include Radio Frequency Identification (RFID) tag readers, NFC detectors, optical sensors (for example, one-or multi-dimensional bar codes, or other optical codes), and/or acoustic detectors (for example, microphones to identify tagged audio signals). In some examples, location information may be determined based on information from the communication components 864, such as, but not limited to, geo-location via Internet Protocol (IP) address, location via Wi-Fi, cellular, NFC, Bluetooth, or other wireless station identification and/or signal triangulation.

While various embodiments have been described, the description is intended to be exemplary, rather than limiting, and it is understood that many more embodiments and implementations are possible that are within the scope of the embodiments. Although many possible combinations of features are shown in the accompanying figures and discussed in this detailed description, many other combinations of the disclosed features are possible. Any feature of any embodiment may be used in combination with or substituted for any other feature or element in any other embodiment unless specifically restricted. Therefore, it will be understood that any of the features shown and/or discussed in the present disclosure may be implemented together in any suitable combination. Accordingly, the embodiments are not to be restricted except in light of the attached claims and their equivalents. Also, various modifications and changes may be made within the scope of the attached claims.

Generally, functions described herein (for example, the features illustrated in FIGS. 1-8) can be implemented using software, firmware, hardware (for example, fixed logic, finite state machines, and/or other circuits), or a combination of these implementations. In the case of a software implementation, program code performs specified tasks when executed on a processor (for example, a CPU or CPUs). The program code can be stored in one or more machine-readable memory devices. The features of the techniques described herein are system-independent, meaning that the techniques may be implemented on a variety of computing systems having a variety of processors. For example, implementations may include an entity (for example, software) that causes hardware to perform operations, e.g., processors functional blocks, and so on. For example, a hardware device may include a machine-readable medium that may be configured to maintain instructions that cause the hardware device, including an operating system executed thereon and associated hardware, to perform operations. Thus, the instructions may function to configure an operating system and associated hardware to perform the operations and thereby configure or otherwise adapt a hardware device to perform functions described above. The instructions may be provided by the machine-readable medium through a variety of different configurations to hardware elements that execute the instructions.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

The scope of protection is limited solely by the claims that now follow. That scope is intended and should be interpreted to be as broad as is consistent with the ordinary meaning of the language that is used in the claims when interpreted in light of this specification and the prosecution history that follows, and to encompass all structural and functional equivalents. Notwithstanding, none of the claims are intended to embrace subject matter that fails to satisfy the requirement of Sections 101, 102, or 103 of the Patent Act, nor should they be interpreted in such a way. Any unintended embracement of such subject matter is hereby disclaimed.

Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein.

Relational terms such as first and second and the like may be used solely to distinguish one entity or action from another without necessarily requiring or implying any actual such relationship or order between such entities or actions. The terms “comprises,” “comprising,” and any other variation thereof, are intended to cover a non-exclusive inclusion, such that a process, method, article, or apparatus that comprises a list of elements does not include only those elements but may include other elements not expressly listed or inherent to such process, method, article, or apparatus. An element preceded by “a” or “an” does not, without further constraints, preclude the existence of additional identical elements in the process, method, article, or apparatus that comprises the element.

What is claimed is:

1. A data processing system for production of custom-fit furniture, the data processing system comprising:
a processor; and
a memory in communication with the processor, the memory comprising executable instructions that, when executed by the processor alone or in combination with other processors, cause the data processing system to perform functions of:
receiving measurement data that quantify a plurality of proportions of a human body;
determining, via a custom-fit design engine, based on the measurement data, dimensions for one or more parts that make up a furniture item; and
generating an electronic design file based on the determined dimensions, the electronic design file providing a specification of dimensions and one or more shapes for the one or more parts of the furniture item, the electronic design file identifying a plurality of lines along a material from which the one or more parts of the furniture item are to be produced, and the electronic design file identifying a bend to be made along one or more of the plurality of lines and an indication of a number of degrees of each bend along the plurality of lines to form the one or more parts of the furniture item,
wherein the electronic design file is used to cut a single sheet of a bendable material by a computer-aided manufacturing machine in accordance with the specification of the dimensions, the single sheet being configured to be bent and assembled into the furniture item.

2. The data processing system of claim 1, wherein the specification of the dimensions are in a predetermined proportion to the plurality of proportions of the human body.

3. The data processing system of claim 1, wherein the furniture item includes a custom-fit chair.

4. The data processing system of claim 1, wherein the computer-aided manufacturing machine operable to perform the cutting includes at least one of a laser computer-aided manufacturing machine, a plasma computer-aided manufacturing machine, a waterjet computer-aided manufacturing machine or a router computer-aided manufacturing machine.

5. The data processing system of claim 1, wherein the cut sheet of the bendable material is bended by a computer-aided manufacturing machine in accordance with the specification of the dimensions.

6. The data processing system of claim 1, wherein the bendable material is steel.

7. The data processing system of claim 1, wherein the sheet of the bendable material is a flat sheet of the bendable material.

8. The data processing system of claim 1, wherein the cut sheet of the bendable material generates the one or more parts of the furniture item.

9. The data processing system of claim 1, wherein the one or more parts are used to assemble the furniture item.

10. A method for mass production of custom-fit furniture, the method comprising:
receiving measurement data that quantify a plurality of proportions of a human body via a user interface of an application;
receiving one or more parameters related to a desired furniture item;
determining, via a custom-fit design engine, based on at least the measurement data and the one or more parameters, dimensions for one or more parts that make up the desired furniture item; and
generating an electronic design file based on the determined dimensions, the electronic design file providing a specification of dimensions and one or more shapes for the one or more parts of the furniture item, the electronic design file identifying a plurality of lines along a material from which the one or more parts of the furniture item are to be produced, and the electronic design file identifying a bend to be made along one or more of the plurality of lines and an indication of a number of degrees of each bend along the plurality of lines to form the one or more parts of the furniture item,
wherein the electronic design file is used to cut a sheet of a bendable material by a computer-aided manufacturing machine in accordance with the electronic design file.

11. The method of claim 10, wherein the computer-aided manufacturing machine includes at least one of a laser computer-aided manufacturing machine, a plasma computer-aided manufacturing machine, a waterjet computer-aided manufacturing machine or a router computer-aided manufacturing machine.

12. The method of claim 10, wherein the custom-fit design engine is a software program for automatically generating design files for custom-fit furniture.

13. The method of claim 12, wherein the custom-fit design engine is generated using a 3D computer-aided design (CAD) application.

14. The method of claim 10, wherein the specification of the dimensions are in a predetermined proportion to the plurality of proportions of the human body.

15. The method of claim 10, wherein the cut sheet of the bendable material generates the one or more parts of the furniture item.

16. The method of claim 15, further comprising bending the cut sheet manually to generate the one or more parts of the furniture item.

17. The method of claim 10, wherein the furniture items includes at least one of a chair, a table, a bench, a desk, a sofa or a loveseat.

18. A custom-fit furniture item comprising:
a plurality of parts, each part having one or more dimensions and each part forming a shape; and
one or more connecting elements for connecting the plurality of parts to produce the custom-fit furniture item,
wherein:
the one or more dimensions are determined based on measurement data that quantify a plurality of proportions of a human body, and
the plurality of parts are made from a material which is cut from a single sheet using an electronic design file generated for the custom-fit furniture item, the electronic design file identifying a plurality of lines along the material and identifying a bend to be made along one or more of the plurality of lines and an indication of a number of degrees of each bend along the plurality of lines to form the plurality of parts of the furniture item;
the plurality of parts are used to assemble the custom-fit furniture.

19. The custom-fit furniture item of claim 18, wherein the custom-fit furniture item includes one of a chair, a table, a bench, a desk, a sofa, a bed or a loveseat.

20. The custom-fit furniture item of claim 18, wherein the electronic design file is used to cut a sheet of the material by a computer-aided manufacturing machine in accordance with a specification of the one or more dimensions and wherein the computer-aided manufacturing machine includes at least one of a laser computer-aided manufacturing machine, a plasma computer-aided manufacturing machine, a waterjet computer-aided manufacturing machine or a router computer-aided manufacturing machine.
